(19) United States
(12) Patent Application Publication
(10) Pub. No.: US 2008/0018239 A1
(43) Pub. Date: Jan. 24, 2008

(54) DISPLAY AND METHOD FOR MANUFACTURING DISPLAY

(75) Inventors: Eisuke Matsuda, Kanagawa (JP); Ryoko Takagi, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 11/777,425

(22) Filed: Jul. 13, 2007

(30) Foreign Application Priority Data
Jul. 21, 2006 (JP) 2006-198844

(51) Int. Cl. H01J 1/62; H01J 9/02; H01L 51/54; H01L 51/56

(52) U.S. Cl. 313/504; 445/24

(57) ABSTRACT

Disclosed herein a display including: a plurality of organic electroluminescent elements configured to be arranged over a substrate and be each obtained by depositing a lower electrode, an organic layer including at least a light-emitting layer, and an upper electrode in that order, the organic layer of each of the organic electroluminescent elements being adjusted to have a film thickness that allows resonance of a wavelength of luminescent light generated in the light-emitting layer, wherein the film thickness of the organic layer in a first organic electroluminescent element that generates luminescent light having a shortest wavelength among the plurality of organic electroluminescent elements is set larger than the film thickness of the organic layer in a second organic electroluminescent element that generates luminescent light having a wavelength longer than the shortest wavelength of luminescent light generated in the first organic electroluminescent element.

### CROSS REFERENCES TO RELATED APPLICATIONS

The present invention contains subject matter related to Japanese Patent Application JP 2006-198844, filed in the Japan Patent Office on Jul. 21, 2006, the entire contents of which being incorporated herein by reference.

### BACKGROUND OF THE INVENTION

1. Field of the Invention

The present invention relates to a display and a method for manufacturing the same, and particularly to a display including organic electroluminescent elements of plural colors and a method for manufacturing the same.

2. Description of the Related Art

In recent years, as an alternative to CRT displays, flat panel displays with a smaller weight and lower power consumption are being researched and developed. Among flat panel displays, displays using organic electroluminescent elements are self-luminous displays and have high response speed, and therefore are attracting attention as displays that can be driven with low power consumption.

In order to achieve a full-color display, organic electroluminescent elements that respectively emit red (R) light, green (G) light, and blue (B) light are arranged. Furthermore, there has been proposed a micro cavity structure for resonating light generated in the light-emitting layer between the anode and the cathode and emitting the resonated light from the anode side or the cathode side. This structure can enhance the color purity of the output light and enhance the intensity of output light of the target wavelength.

In such a display, the optical distances Lr, Lg, and Lb between the cathode and the anode of the organic electroluminescent elements of R, G, and B are adjusted by the film thicknesses of the organic layer in the respective elements. The optical distances Lr, Lg, and Lb are so designed that light with the peak wavelengths λr, λg, and λb in the spectra of the output light will be resonated between the cathode and the anode.

By adjusting the optical distances Lr, Lg, and Lb with film thicknesses of the light-emitting layer of respective color, other layers of the organic layer can be commonly provided in all the organic electroluminescent elements.

As a method for providing patterns of the light-emitting layers of the respective colors, laser transfer method has been proposed. Laser transfer method is carried out as follows for example. Initially, an anode is formed on a substrate of the display (hereinafter, referred to as a display substrate). On the other hand, on another substrate (hereinafter, referred to as a transfer substrate), a light absorption layer and a light-emitting layer are provided. Subsequently, the display substrate and the transfer substrate are so disposed that the light-emitting layer and the anode face each other. Laser is irradiated to the back surface of the transfer substrate and the light-emitting layer is thermally transferred onto the anode on the display substrate. In this step, laser beam is scanned over the transfer substrate, and the transfer pattern of the light-emitting layer is formed only on a predetermined region on the anode with high accuracy.

As an application of this laser transfer method, there has been proposed a process in which light-emitting layers of red (R) and green (G) are provided for the organic electroluminescent elements of each color by laser transfer and a light-emitting layer of blue (B) is provided for the organic electroluminescent elements of all color by evaporation. Therefore, in accordance with the order of the peak wavelengths λr>λg>λb, the optical distances Lr, Lg, and Lb satisfy the relationship Lr>Lg>Lb. In addition, in accordance with these optical distances, the film thicknesses of the organic layer in the organic electroluminescent elements of the respective colors are designed to be in the order R>G>B (refer to Japanese Patent Laid-open No. 2005-235741).

However, if the film thicknesses of the organic layers of the respective colors are designed to follow the order of the wavelengths of emitted light as described above, the organic layer of B, of which wavelength of emitted light is the shortest, is formed as the thinnest film, and thus is susceptible to the external damage. Consequently, the organic electroluminescent elements of B involve more defective spots compared with the elements of the other colors.

In addition, in general film deposition including laser transfer method, the larger a target film thickness is, the larger the error amount between the target film thickness and the film thickness actually deposited. Therefore, if the film thicknesses of organic films are designed to be in the order R>G>B as described above, the amounts of the film thickness error are also in this order. However, in general, the sensitivity (CIE standard spectral luminous efficiency: luminosity factor) of human's eyes to the respective colors is in the order G>R>B (the sensitivity to G is the highest). Therefore, the degree of necessity for the accuracy of the peak wavelength λ in the spectrum of output light, i.e., for the accuracy of the film thickness of the organic layer, is also in the order G>R>B. Specifically, the highest thickness accuracy is required for the organic layer of G, of which the luminosity factor is the highest. Thus, it is preferable that the thicknesses of transferred films be in the order G<R<B in terms of control of light emission characteristics.

### SUMMARY OF THE INVENTION

There is a need for the present invention to provide, as a full-color display including organic electroluminescent elements of the respective colors, a display that is allowed to include reduced defective spots in organic electroluminescent elements for a specific luminescent color, while ensuring the controllability of light emission characteristics.

According to an aspect of the present invention, there is provided a display that includes a plurality of organic electroluminescent elements arranged over a substrate. Each of the organic electroluminescent elements is obtained by depositing a lower electrode, an organic layer including at least a light-emitting layer, and an upper electrode in this order. The organic layer in these organic electroluminescent elements is adjusted to have a film thickness that allows resonance of the wavelength of luminescent light generated in the light-emitting layer. In particular, in the display, the film thickness of the organic layer in the first organic electroluminescent element that generates first color luminescent light is set larger than the film thickness of the organic layer in the second organic electroluminescent element that generates second color luminescent light having a wavelength longer than the wavelength of the first color luminescent light.

According to another aspect of the present invention, there is provided a method for manufacturing a display.

In the display with the above-described configuration, because the first organic electroluminescent element that generates first color luminescent light (blue luminescent light) is provided as the thickest organic layer, the occurrence of defective spots in the first organic electroluminescent element is prevented. Furthermore, as shown in WORKING EXAMPLE to be described later, it is confirmed that even when the film thickness of an organic layer in organic electroluminescent elements that generate blue luminescent light is thus increased, variation in the light emission efficiency due to the increase in the film thickness is sufficiently small.

As described above, according to the embodiments of the present invention, in a full-color display including organic electroluminescent elements of the respective colors, defective spots in organic electroluminescent elements for a specific luminescent color can be reduced without failure in the controllability of light emission characteristics.

### BRIEF DESCRIPTION OF THE DRAWINGS

FIG. 1 is a sectional view showing the configuration of a display according to an embodiment of the present invention;

FIGS. 2(1) to 2(3) are sectional views showing steps in a method for manufacturing the display according to the embodiment;

FIGS. 3(1) and 2(2) are sectional views showing steps in the method for manufacturing the display according to the embodiment; and

FIGS. 4(1) and 4(2) are sectional views showing steps in the method for manufacturing the display according to the embodiment.

### DETAILED DESCRIPTION OF THE PREFERRED EMBODIMENTS

An embodiment of the present invention will be described in detail below with reference to the drawings.

In the following description, the embodiment of the present invention is applied to a display having a configuration in which organic electroluminescent elements of the respective colors of red (R), green (G), and blue (B) are arranged over a substrate for full-color displaying.

### <Display>

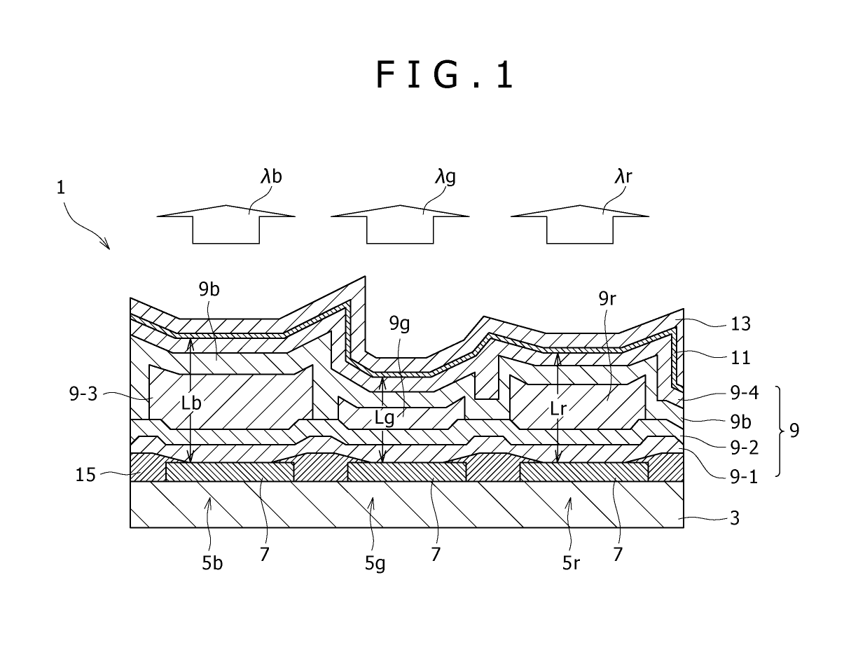

FIG. 1 is a diagram showing the configuration of a display according to the embodiment. A display 1 shown in FIG. 1 is obtained by arranging over a substrate 3 organic electroluminescent elements 5r, 5g, and 5b that emit light of the respective colors of red (R), green (G), and blue (B), i.e., the red light-emitting elements 5r, the green light-emitting elements 5g, and the blue light-emitting elements 5b. The display 1 is formed as a top-emission display that outputs luminescent light generated in the respective light-emitting elements 5r, 5g, and 5b from the opposite side of the substrate 3.

The substrate 3 is a so-called TFT substrate obtained by arranging thin film transistors (TFTs, not shown in FIG. 1) on the surface layer of a glass substrate, silicon substrate, plastic substrate, or the like. The surface of the substrate 3 is covered by a planarization insulating film.

The light-emitting elements 5r, 5g, and 5b arranged over the substrate 3 have a structure obtained by sequentially depositing an anode (lower electrode) 7, an organic layer 9, an electron injection layer 11, and a cathode (upper electrode) 13 in that order from the substrate 3. With the anode 7 used as a light reflective layer and the cathode 13 used as a semi transmissive/reflective layer, the light-emitting elements 5r, 5g, and 5b are formed to have a micro resonator structure for resonating light λr, λg, and λb having a specific wavelength generated in the light-emitting elements 5r, 5g, and 5b and outputting the resonated light from the cathode 13.

Specifically, for the red light-emitting element 5r, the optical distance Lr of the resonating part between the anode 7 and the cathode 7 is so adjusted that the light λr in the red wavelength region will be resonated in the resonating part and the maximum light extraction efficiency is obtained. Furthermore, for the green light-emitting element 5g, the optical distance Lg of the resonating part between the anode 7 and the cathode 13 is so adjusted that the light λg in the green wavelength region will be resonated in the resonating part and the maximum light extraction efficiency is obtained. Moreover, for the blue light-emitting element 5b, the optical distance Lb of the resonating part between the anode 7 and the cathode 13 is so adjusted that the light λb in the blue wavelength region will be resonated in the resonating part and the maximum light extraction efficiency is obtained. Thus, from the respective light-emitting elements 5r, 5g, and 5b, the light λr, λg, and λb of different luminescent colors is extracted with sufficient intensity.

In the display 1 provided with such light-emitting elements 5r, 5g, and 5b, the blue light-emitting element 5b serves as the first organic electroluminescent element that generates luminescent light having the shortest wavelength. Furthermore, the red light-emitting element 5r and the green light-emitting element 5g serve as the second organic electroluminescent element that generates light having a wavelength longer than that of the luminescent light generated in the first organic electroluminescent element.

When the phase shift that occurs when light generated in the light-emitting elements 5r, 5g, and 5b is reflected at an end of the resonating part is represented as Φ (radian), the optical distance of the resonating part is represented as L, and the peak wavelength in the spectrum of output light is represented as λ, the above-described optical distance L (Lr, Lg, Lb) is designed to satisfy Equation (1).

(2L)/λ+Φ/(2n)=m(m is an integer number) Equation (1)

If all the optical distances Lb, Lr, and Lg are designed to offer m corresponding to the interference condition of the same order, e.g., the zero-order interference condition, the distances are in the order Lr>Lg>Lb. In contrast, in the present embodiment, in order that the film thickness of the organic layer 9 in the blue light-emitting element 5b that generates luminescent light having the shortest wavelength may be larger than those of the organic layer in the red light-emitting element 5r and the green light-emitting element 5g, the optical distance Lr of the red light-emitting element 5r and the optical distance Lg of the green light-emitting element 5g are designed to satisfy the zero-order interference condition like existing distance design, while only the optical distance Lb of the blue light-emitting element 5b is designed to satisfy the first-order interference condition. These optical distances Lr, Lg, and Lb are adjusted through control of the film thicknesses of the organic layer 9 in the respective organic electroluminescent elements 5r, 5g, and 5b as described later.

A description will be made below about the respective layers included in the light-emitting elements 5r, 5g, and 5b having the above-described micro resonator structure.

Patterns of the anode 7 are formed for the respective pixels. Each anode 7 is connected to a corresponding one of TFTs provided for the respective pixels similarly via a contact hole (not shown) formed in an interlayer insulating film that covers the TFTs.

The anode 7 is formed as a mirror by using a highly reflective material. Such an anode 7 is composed of any of the following conductive materials with high reflectivity and alloys of the materials: silver (Ag), aluminum (Al), chromium (Cr), iron (Fe), cobalt (Co), nickel (Ni), copper (Cu), tantalum (Ta), tungsten (W), platinum (Pt), and gold (Au).

The anode 7 may have a structure in which a barrier layer is provided on a conductive material layer. In this case, the barrier layer is composed of a material having a large work function and has a thickness of about 1 nm to 200 nm. This barrier layer may be composed of any material as long as the anode 7 is formed as a highly reflective layer. When the conductive material layer is composed of a highly reflective material, the barrier layer is composed of an optically transparent material. When the optical reflectivity of the conductive material is low, a highly reflective material is used for the barrier layer.

Such a barrier layer is composed of a material that is adequately selected, in consideration of the combination with the above-described conductive material layer, from optically transparent materials including at least one of the following metals, an alloy of any of the metals, a metal oxide of any of the metals, or a metal nitride of any of the metals: indium (In), tin (Sn), zinc (Zn), cadmium (Cd), titanium (Ti), chromium (Cr), gallium (Ga), and aluminum (Al). Examples of the alloy include an indium-tin alloy and indium-zinc alloy. Examples of the metal oxide include indium-tin-oxide (ITO), indium-zinc-oxide (IZO), indium oxide (In₂O₃), tin oxide (SnO₂), zinc oxide (ZnO), cadmium oxide (CdO), titanium oxide (TiO₂), and chromium oxide (CrO₂). Examples of the metal nitride include titanium nitride and chromium nitride (CrN).

The peripheries of the anodes 7, which are each formed for a respective one of the pixels, are covered by an insulating film 15 in such a way that only the center parts of the anodes 7 are exposed. This insulating film 15 is composed of an organic insulating material such as polyimide or photoresist, or an inorganic insulating material such as a silicon oxide.

The organic layer 9 provided on the anodes 7 is obtained by sequentially depositing a hole injection layer 9-1, a hole transport layer 9-2, a red light-emitting pattern layer 9r, a green light-emitting pattern layer 9g, a film-thickness adjustment pattern layer 9-3 that are provided on a pixel basis, a blue common light-emitting layer 9b provided as a common layer, and anelectron transport layer 9-4 in that order.

Of these layers, the red light-emitting pattern layer 9r, the green light-emitting pattern layer 9g, and the film-thickness adjustment pattern layer 9-3 are each formed by laser transfer method as a pattern for a respective one of the light-emitting elements 5r, 5g, and 5b. On the other hand, the other layers including the blue common light-emitting layer 9b are provided by evaporation as a common layer for all the light-emitting elements 5r, 5g, and 5b.

Details of each of these layers and pattern layers included in the organic layer 9 will be described below sequentially from the anode side.

The hole injection layer 9-1 is provided as a common layer for all the pixels in such a manner as to cover the anodes 7 and the insulating film 15. Such a hole injection layer 9-1 is composed of a general hole injection material. As one example, the hole injection layer 9-1 is deposited by evaporation to a film thickness of 10 nm by using m-MTDATA [4,4,4-tris(3-methylphenylphenylamino)triphenylamine].

The hole transport layer 9-2 is provided on the hole injection layer 9-1 as a common layer for all the pixels. Such a hole transport layer 9-2 is composed of a general hole transport material, and specifically is composed of e.g. a benzine derivative, styrylamine derivative, triphenylmethane derivative, or hydrazone derivative. As one example, the hole transport layer 9-2 is deposited by evaporation to a film thickness of 15 nm by using A-NPD [4,4-bis(N-1-naphthyl-N-phenylamino)biphenyl].

Each of the hole injection layer 9-1 and the hole transport layer 9-2 may have a multi-layer structure formed of plural layers.

The red light-emitting pattern layer 9r is formed as a pattern that completely covers an aperture window formed in the insulating film 15 in a pixel area of the red light-emitting element 5r. The red light-emitting pattern layer 9r is composed of a host material and a guest material. As the host material, at least one kind of hole-transport host materials, electron-transport host materials, and hole-and-electron-transport host materials. For example, ADN (anthracene dinaphtyl), which is an electron-transport host material, is available. As the guest material, a fluorescent or phosphorescent red light-emitting material is used. For example, 2,6-bis[(4′-methoxydiphenylamino)styryl]-1,5-dicyanonaphthalene (BSN) is available. The amount ratio of the guest material to the total amount of the host and guest materials is about 30 wt. %. The film thickness of the red light-emitting pattern layer 9r having such a structure is set to e.g. 35 nm.

The green light-emitting pattern layer 9g is formed as a pattern that completely covers an aperture window formed in the insulating film 15 in a pixel area of the green light-emitting element 5g. The green light-emitting pattern layer 9g is composed of a host material, a guest material, and an organic material for decreasing the resistance. As the host material, a material similar to the host material of the red light-emitting pattern layer 9r is used, and e.g. ADN (anthracene dinaphtyl) is available. As the guest material, a fluorescent or phosphorescent green light-emitting material is used, and e.g. coumarin 6 is available. The amount ratio of the guest material to the total amount of the host and guest materials is about 5 wt. %. The film thickness of the green light-emitting pattern layer 9g having such a structure is set to e.g. 15 nm.

The film-thickness adjustment pattern layer 9-3 is formed as a pattern that completely covers an aperture window formed in the insulating film 15 in a pixel area of the blue light-emitting element 5b. This film-thickness adjustment pattern layer 9-3 is formed as a layer that does not contain a luminescent material but has a hole transport function.

Furthermore, the film-thickness adjustment pattern layer 9-3 is the thickest transferred-pattern layer as described later. Therefore, it is preferable that the film-thickness adjustment pattern layer 9-3 be composed of a material having a lower molecular weight and lower sublimation temperature compared with the materials of the red light-emitting pattern layer 9r and the green light-emitting pattern layer 9g, which are used for the other colors. Furthermore, the film-thickness adjustment pattern layer 9-3 is provided in contact with the anode-side surface of the blue common light-emitting layer 9b to be described next. Therefore, it is preferable for the film-thickness adjustment pattern layer 9-3 to have high electron block performance. As such a hole transport material, e.g. A-NPD [4,4-bis(N-1-naphthyl-N-phenylamino)biphenyl] having a film thickness of 125 nm is used. A material having an arylamine backbone such as A-NPD has high electron block performance, and therefore is suitable as the material of the film-thickness adjustment pattern layer 9-3 formed in contact with the anode-side surface of the blue common light-emitting layer 9b to be described next.

The film-thickness adjustment pattern layer 9-3 may be provided between the hole transport layer 9-2 and the hole injection layer 9-1. In this structure, the hole transport layer 9-2 is formed in contact with the blue common light-emitting layer 9b, and thus the film-thickness adjustment pattern layer 9-3 does not need to have high electron block performance.

When such a structure is employed, as the hole transport material of the film-thickness adjustment pattern layer 9-3, a material that has high hole transport performance and is readily sublimed can be selectively used. As such a hole transport material, e.g. a compound represented by Formula (1) is available.

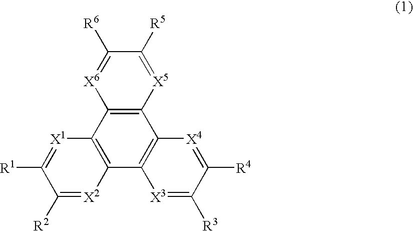

In Formula (1), R1 to R6 are substituents independently selected from hydrogen, a halogen, hydroxyl group, amino group, arylamino group, substituted or unsubstituted carbonyl group having 20 or less carbon atoms, substituted or unsubstituted carbonyl ester group having 20 or less carbon atoms, substituted or unsubstituted alkyl group having 20 or less carbon atoms, substituted or unsubstituted alkenyl group having 20 or less carbon atoms, substituted or unsubstituted alkoxyl group having 20 or less carbon atoms, substituted or unsubstituted aryl group having 30 or less carbon atoms, substituted or unsubstituted heterocyclic group having 30 or less carbon atoms, nitrile group, cyano group, nitro group, and silyl group. Adjacent groups of the groups R1 to R6 may be coupled to each other to form a cyclic structure. X1 to X6 in Formula (1) are each independently a carbon or nitrogen atom.

As a specific example of such a compound, a compound represented by Formula (2) is available. The compound of Formula (2) is a material that is very readily sublimed, and hence a structure containing such a material allows highly accurate transfer.

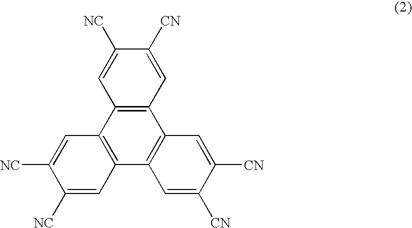

A specific example of the compound of Formula (1) is not limited to the structure represented by Formula (2), but a structure obtained by independently replacing the parts R1 to R6 and the parts X1 to X6 in Formula (1) by any of the substituents described for Formula (1) is available.

The film-thickness adjustment pattern layer 9-3 may be formed of a multi-layer or mixed layer employing A-NPD and a material represented by Formula (1). However, when the film-thickness adjustment pattern layer 9-3 is formed in contact with the anode-side surface of the blue common light-emitting layer 9b, the interface layer of the film-thickness adjustment pattern layer 9-3 in contact with the blue common light-emitting layer 9b is composed of a material having high electron block performance.

As described above, the optical distances Lr, Lg, and Lb of the respective light-emitting elements 5r, 5g, and 5b are so adjusted that light having a specific wavelength will be resonated between the anode 7 and the cathode 13. In the present embodiment, the optical distances Lr, Lg, and Lb are adjusted through control of differences in the film thickness of the above-described red light-emitting pattern layer 9r, the green light-emitting pattern layer 9g, and the film-thickness adjustment pattern layer 9-3.

Therefore, when the optical distances Lr, Lg, and Lb of the resonating part in the respective light-emitting elements 5r, 5g, and 5b are represented as L, the optical distances of the respective pattern layers 9r, 9g, and 9-3 are represented as Lt, and the optical distances of the common functional layers other than these pattern layers are represented as Lf, the optical distances Lt of the pattern layers 9r, 9g, and 9-3, i.e., the film thicknesses of these pattern layers, are designed to satisfy the equation Lt=L−Lf.

In the present embodiment in particular, as described above, the optical distances Lr, Lg, and Lb of the resonating part in the respective light-emitting elements 5r, 5g, and 5b are so designed that the optical distance Lr of the red light-emitting element 5r and the optical distance Lg of the green light-emitting element 5g satisfy the zero-order interference condition like existing distance design while only the optical distance Lb of the blue light-emitting element 5b satisfies the first-order interference condition. Therefore, the optical distances Lt (film thicknesses) of these pattern layers 9r, 9g, and 9-3 are in the order 9g<9r<9-3.

The blue common light-emitting layer 9b that covers the above-described pattern layers 9r, 9g, and 9-3 is provided as a common layer for all the pixels. This blue common light-emitting layer 9b functions as a light-emitting layer in the blue light-emitting element 5b. In contrast, it does not function as a light-emitting layer in the red light-emitting element 5r and the green light-emitting element 5g. Alternatively, it is provided as a layer that emits blue light but has no effect on emitted red and green light, of which wavelengths are longer than that of the blue light.

Such a blue common light-emitting layer 9b is composed of ADN doped with 2.5-wt. % 4,4′-bis[2-(4-(N,N-diphenylamino)phenyl)vinyl]biphenyl (DPAVBi) and having a film thickness of about 25 nm.

The electron transport layer 9-4 on the blue common light-emitting layer 9b is composed of a general electron transport material. As one example, the electron transport layer 9-4 is deposited by evaporation to a film thickness of about 20 nm by using 8-hydroxyquinoline aluminum (Alq3).

The electron injection layer 11 on the organic layer 9 formed of the above-described respective layers is provided as a common layer for all the pixels. Such an electron injection layer 11 is composed of a general electron injection material. As one example, the electron injection layer 11 is formed by depositing LiF by evaporation to a film thickness of about 0.3 nm.

The cathode 13 on the electron injection layer 11 is provided as a common layer for all the pixels. Such a cathode 13 is composed of a conductive material having a small work function. As such a conductive material, e.g. an alloy of an active metal such as Li, Mg, or Ca and a metal such as Ag, Al, or In, or a multi-layer structure of any of these metals can be used. This cathode 13 is used a half-mirror, and therefore the film thickness thereof is so adjusted depending on its material that the reflectivity thereof is at least 0.1% and lower than 50%. As such a cathode 13, e.g. an MgAg film with a film thickness of 10 nm is used. Furthermore, at the interface with the electron injection layer 11, e.g. a thin compound layer composed of an active metal such as Li, Mg, or Ca, a halogen such as fluorine or bromine, oxygen, and so on may be interposed.

When the cathode 13 is used as a common electrode for all the pixels as described above, an auxiliary electrode (not shown) may be formed by the same layer as the anodes 7 and the cathode 13 may be connected to the auxiliary electrode to thereby prevent a voltage drop of the cathode 13. The organic layer deposited over the auxiliary electrode can be removed by laser ablation or the like immediately before the deposition of the cathode 13.

The light-emitting elements 5r, 5g, and 5b formed of the above-described respective layers are covered by a protective film (not shown). Furthermore, a sealing substrate is applied onto this protective film by using an adhesive, so that the full-solid-state display 1 is formed.

The protective film is formed to have a sufficiently large film thickness by using a material with low water permeability and low water absorption in order to prevent water from reaching the organic layer 9. Furthermore, because the display 1 to be fabricated is a top-emission display, this protective film is composed of a material that allows transmission of light generated in the light-emitting elements 5r, 5g, and 5b. For example, a transmittance of about 80% is ensured for the protective film. Such a protective film may be composed of an insulating material or conductive material. When the protective film is composed of an insulating material, an inorganic amorphous insulating material such as amorphous silicon (α-Si), amorphous silicon carbide (α-SiC), amorphous silicon nitride (α-Sil-xNx), or amorphous carbon (α-C) can be preferably used. Such an inorganic amorphous insulating material includes no grain and thus has low water permeability, and hence serves as a favorable protective film. When the protective film is composed of a conductive material, a transparent conductive material such as ITO or IZO is used.

As the adhesive, e.g. a UV-curable resin is used. As the sealing substrate, e.g. a glass substrate is used. It is preferable that the adhesive and the sealing substrate be composed of a material having optical transparency.

Above the cathode 13 (light-output side), a color filter may be provide that allows transmission of light in a predetermined wavelength region resulting from resonance in the resonating part and output from the resonating part. The provision of a color filter further enhances the color purity of light extracted from the light-emitting elements 5r, 5g, and 5b of the respective colors.

### <Method for Manufacturing Display>

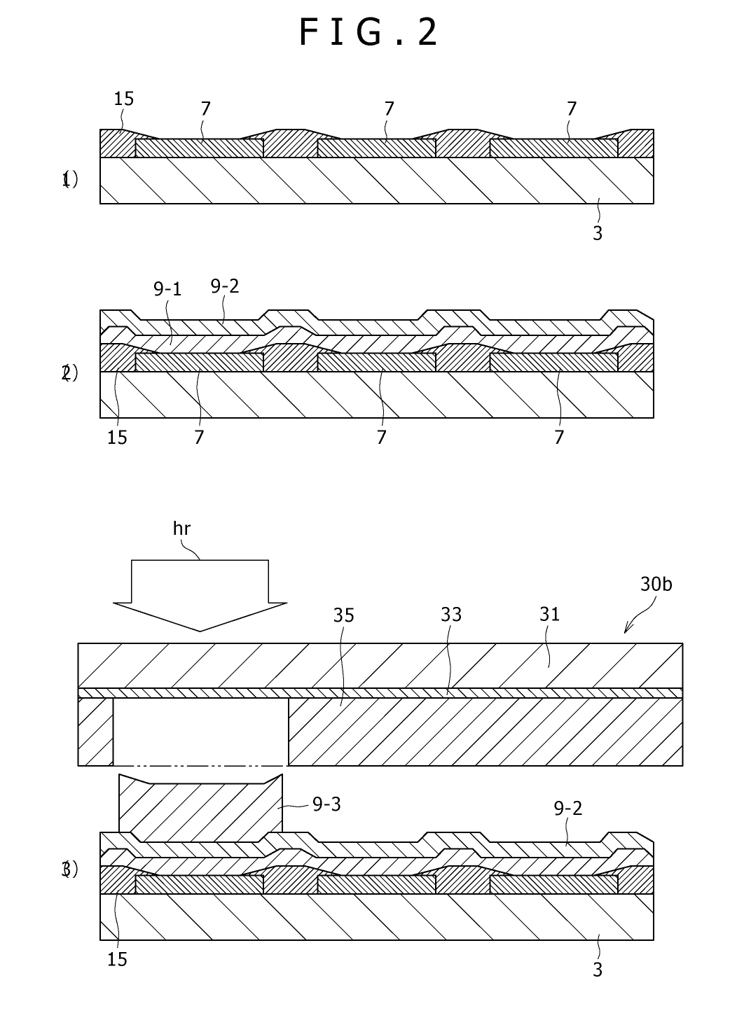

A method for manufacturing the display 1 having the above-described configuration will be described below with reference to FIGS. 2 to 4, which are sectional views showing manufacturing steps. Of the respective layers to be shown below, the same layers as those already described with FIG. 1 will not be described redundantly.

Referring initially to FIG. 2(1), patterns of the highly reflective anodes 7 are formed, and then the insulating film 15 is formed into a shape exposing the center parts of these anodes 7.

Referring next to FIG. 2(2), the hole injection layer 9-1 is deposited by evaporation over the entire surface of the substrate 3 in such a manner as to cover the anodes 7 and the insulating film 15, followed by deposition of the hole transport layer 9-2 by evaporation.

Subsequently, steps of forming the respective pattern layers by laser transfer for the respective pixels on the thus formed hole transport layer 9-2 are sequentially carried out.

Initially, as shown in FIG. 2(3), a transfer substrate 30b is prepared. In this transfer substrate 30b, over the entire surface of a glass substrate 31 having substantially the same shape as that of the substrate 3 for fabrication of a display, a transfer layer (film-thickness adjustment layer) 35 for forming film-thickness adjustment pattern layers used for blue pixels is provided with the intermediary of a light absorption layer 33.

It is preferable to use, as the material of the light absorption layer 33, a material having low reflectivity with respect to the wavelength region of laser light used as a heat source in the subsequent laser transfer step. For example, when laser light with a wavelength of about 800 nm from a solid-state laser light source is employed, chromium (Cr), molybdenum (Mo), or the like is preferable as the material having low reflectivity and a high melting point, although the material is not limited to these metals. In the present example, the light absorption layer 33 is formed by depositing Cr to a film thickness of 200 nm by sputtering.

The film-thickness adjustment layer 35 is composed of α-NPD[4,4-bis(N-1-naphthyl-N-phenylamino)biphenyl], which offers the hole transport layer described with FIG. 1, and is deposited by evaporation to a film thickness of 125 nm.

The thus formed transfer substrate 30b is disposed to face the substrate 3 over which the hole transport layer 9-2 has been formed. Specifically, the transfer substrate 30b and the substrate 3 are so disposed that the transfer layer 35 for blue and the hole transport layer 9-2 face each other. If the thickness of the insulating film 15 is sufficiently large, the substrate 3 may be brought into close-contact with the transfer substrate 30b, so that the hole transport layer 9-2 as the uppermost layer over the substrate 3 may be brought into contact with the film-thickness adjustment layer 35 as the uppermost layer over the transfer substrate 30b. Even in this case, the transfer substrate 30b is supported over the insulating film 15 of the substrate 3, and thus is not in contact with the parts of the hole transport layer 9-2 over the anodes 7.

Subsequently, the backside of the transfer substrate 30b thus disposed to face the substrate 3 is irradiated with laser light hr with a wavelength of e.g. 800 nm. In this irradiation, the parts corresponding to the formation regions of the blue light-emitting elements are selectively irradiated with a spot beam of the laser light hr.

This irradiation causes the light absorption layer 33 to absorb the laser light hr. By using the heat generated due to the light absorption, the film-thickness adjustment layer 35b is thermally transferred to the substrate 3. Through this operation, on the hole transport layer 9-2 deposited over the substrate 3, the film-thickness adjustment pattern layer 9-3 arising from the laser transfer of the film-thickness adjustment layer 35 with high positional accuracy is formed.

In this step, it is important that the irradiation with the laser light hr be so carried out that the anode 7 exposed from the insulating film 15 in the formation part (pixel region) of the blue light-emitting element will be completely covered by the film-thickness adjustment pattern layer 9-3.

Thereafter, laser transfer steps similar to the above-described step are repeatedly carried out to thereby sequentially form the green light-emitting pattern layers and the red light-emitting pattern layers.

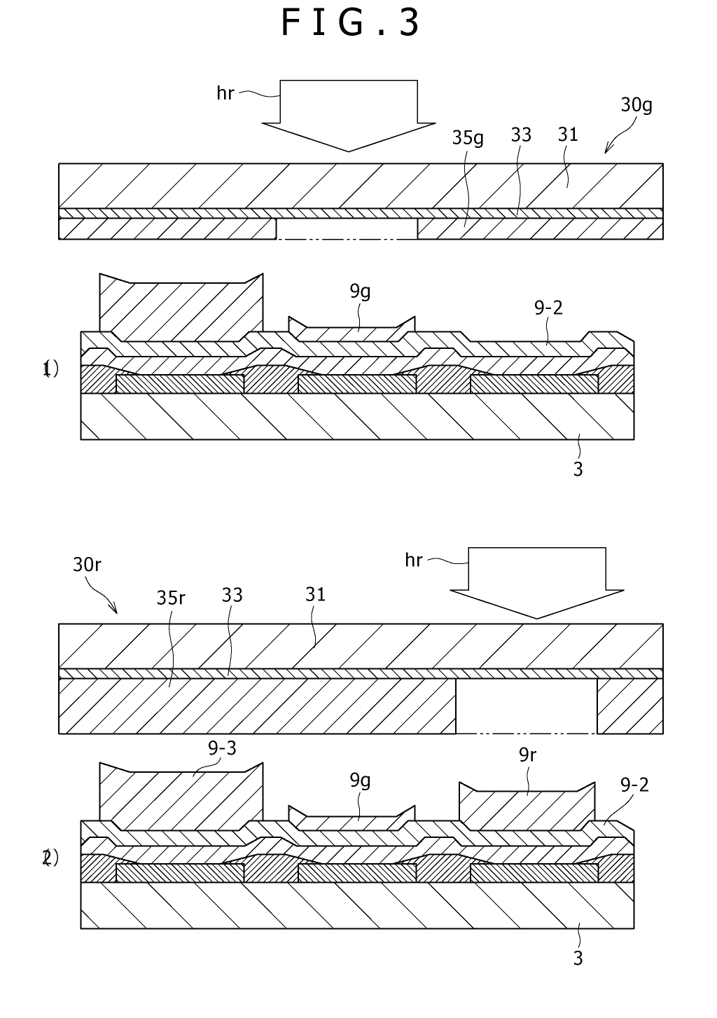

Specifically, as shown in FIG. 3(1), a transfer substrate 30g is prepared by providing, over a glass substrate 31 having substantially the same shape as that of the substrate for fabrication of a display, a transfer layer (green transfer layer) 35g for forming green light-emitting layers with the intermediary of a light absorption layer 33. The green transfer layer 35g of this transfer substrate 30g is composed of a green luminescent guest material as a luminescent guest material.

Specifically, the green transfer layer 35g is composed of e.g. a material obtained by doping ADN (anthracene dinaphtyl) as an electron-transport host material with 5-wt. % coumarin 6 as a green luminescent guest material, and is deposited by evaporation to a film thickness of about 15 nm.

The transfer substrate 30g is disposed to face the substrate 3 over which the hole transport layer 9-2 has been formed. Subsequently, from the backside of the transfer substrate 30g, the parts corresponding to the formation regions of the green light-emitting elements are selectively irradiated with a spot beam of the laser light hr.

This operation forms the green light-emitting pattern layer 9g arising from the selective laser transfer of the green transfer layer 35g on the hole transport layer 9-2 deposited over the substrate 3.

In this laser transfer, the concentration gradient of each of the materials of the green transfer layer 35g of the transfer substrate 30g are adjusted through e.g. control of the irradiation energy of the laser light hr. Specifically, the irradiation energy is set high, to thereby form the green light-emitting pattern layer 9g as a mixed layer arising from substantially homogeneous mixing of the respective materials of the green transfer layer 35g. Alternatively, the irradiation energy may be so adjusted that the mixed layer arising from mixing of the respective materials of the green transfer layer 35g will be provided in the green light-emitting pattern layer 9g.

Subsequently, as shown in FIG. 3(2), a transfer substrate 30r is prepared by providing, over a glass substrate 31 having substantially the same shape as that of the substrate for fabrication of a display, a transfer layer (red transfer layer) 35r for forming red light-emitting layers with the intermediary of a light absorption layer 33. The red transfer layer 35r of this transfer substrate 30r is formed by using the materials contained in the red light-emitting pattern layer (9r). Specifically, the red transfer layer 35r is composed of a host material and a luminescent guest material. Such a red transfer layer 35r is composed of e.g. a material obtained by doping ADN (anthracene dinaphtyl) as an electron-transport host material with 30-wt. % 2,6-bis[(4′-methoxydiphenylamino)styryl]-1,5-dicyanonaphthalene (BSN) as a red luminescent guest material, and is deposited by evaporation to a film thickness of about 35 nm.

The transfer substrate 30r is disposed to face the substrate 3 over which the hole transport layer 9-2 has been formed. Subsequently, from the backside of the transfer substrate 30r, the parts corresponding to the formation regions of the red light-emitting elements are selectively irradiated with a spot beam of the laser light hr.

This operation forms the red light-emitting pattern layer 9r arising from the selective laser transfer of the red transfer layer 35r on the hole transport layer 9-2 deposited over the substrate 3. This laser transfer is so carried out that the red light-emitting pattern layer 9r will be formed with the respective materials of the red transfer layer 35r substantially homogeneously mixed with each other, similarly to the above-described pattern formation of the green light-emitting pattern layer 9g.

It is desirable that the above-described laser transfer steps for the film-thickness adjustment pattern layer 9-3, the green light-emitting pattern layer 9g, and the red light-emitting pattern layer 9r be carried out in a vacuum, although the steps can be carried out also under an atmospheric pressure. The execution of the laser transfer in a vacuum allows transfer with use of laser having lower energy, which can reduce thermal adverse effects on the light-emitting layer to be transferred. Furthermore, the execution of the laser transfer step in a vacuum is desirable because the degree of the contact between the substrates is enhanced and favorable transfer patterning accuracy is obtained. Moreover, if all the process is carried out in a vacuum continuously, deterioration of the elements can be prevented.

In the above-described step of the selective irradiation of a spot beam of the laser light hr, if a laser head drive unit in the laser irradiation apparatus has an accurate alignment mechanism, the laser light hr with a proper spot diameter can be emitted on the transfer substrate (30r, 30g, 30b) along the anodes 7. In this case, there is no need to strictly align the substrate 3 with the transfer substrate (30r, 30g, 30b). In contrast, if the laser head drive unit does not have an accurate alignment mechanism, it is preferable to form a light-shielding film for limiting the region irradiated with the laser light hr on the transfer substrate side. Specifically, on the backside of the transfer substrate, a light-shielding film obtained by providing apertures in a highly reflective metal layer that reflects the laser light is provided. Alternatively, a metal with low reflectivity may be deposited thereon. In this case, it is preferable to accurately align the substrate 3 with the transfer substrate (30r, 30g, 30b).

The order of the laser transfer steps for the film-thickness adjustment pattern layer 9-3, the green light-emitting pattern layer 9g, and the red light-emitting pattern layer 9r is not limited to the above-described order, but any order is available.

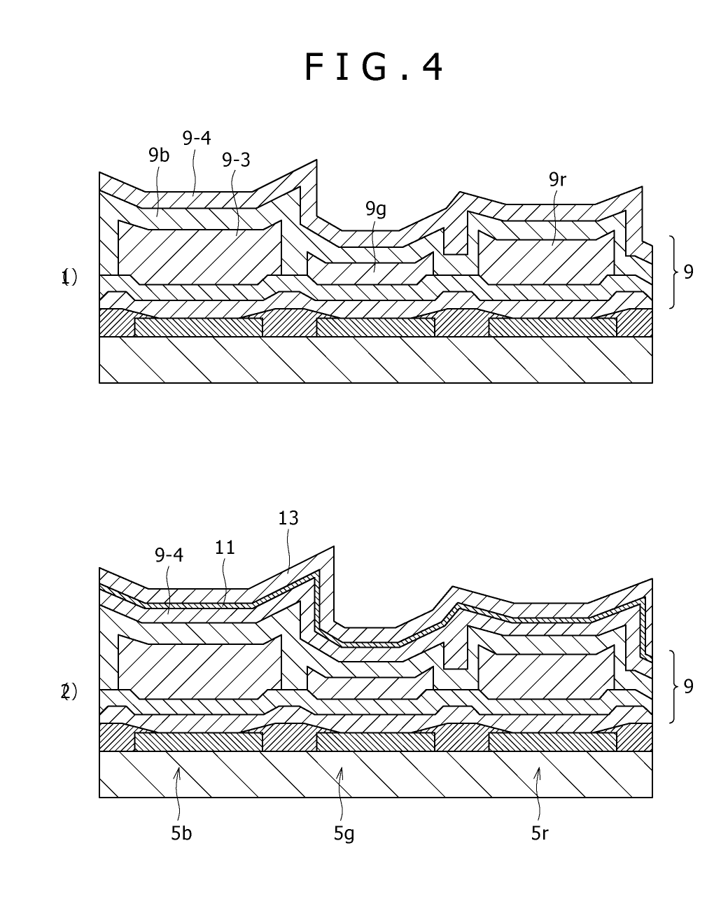

Referring next to FIG. 4(1), the blue common light-emitting layer 9b is deposited by evaporation in such a manner as to cover the entire surface of the substrate 3 over which the respective pattern layers 9r, 9g, and 9-3 have been formed, and then the electron transport layer 9-4 is deposited by evaporation, so that the formation of the organic layer 9 is completed.

Thereafter, as shown in FIG. 4(2), the electron injection layer 11 and the cathode 13 are deposited in that order. It is preferable that these layers be deposited by a method in which the energy of deposition particles is so low that no influence is given to the underlying organic layer 9, such as evaporation or chemical vapor deposition (CVD).

After the organic electroluminescent elements 5r, 5g, and 5b of the respective colors are formed in the above-described manner, a protective film (not shown) is formed. It is desirable that this protective film be deposited at a room temperature as the deposition temperature in order to prevent the lowering of the luminance due to deterioration of the organic layer 9 and be deposited under a condition offering the minimized film stress in order to prevent the protective film from being separated. The display 1 is completed by applying a sealing substrate to the protective film by use of an adhesive.

In the display 1 having the above-described configuration, the organic layer 9 of the blue light-emitting element 5b is provided with the largest film thickness, which prevents the occurrence of defective spots in the blue light-emitting element 5b.

Furthermore, as shown in WORKING EXAMPLE to be described later, it is confirmed that variation in the light emision efficiency can be suppressed sufficiently even when the organic layer 9 of the blue light-emitting element 5b is provided with a large film thickness to satisfy not the zero-order interference condition but the first-order interference condition.

Moreover, the blue common light-emitting layer 9b for the blue light-emitting element 5b is deposited as a common layer by evaporation, and the film-thickness adjustment pattern layer 9-3 is disposed under the blue common light-emitting layer 9b. Due to these features, for the blue light-emitting element 5b, which generally tends to be inferior to the red light-emitting element 5r and the green light-emitting element 5g in the luminescence efficiency and luminance half-lifetime, deterioration (variation in the film thickness and so on) of the blue common light-emitting layer 9b due to the influence of the transfer method can be prevented.

In addition, in the case of blue luminescence, of which luminosity factor is lower than that of green luminescence, it is difficult to visually recognize a color deviation even when the film thickness is increased to prevent the occurrence of defects (i.e., dark dots). This feature also shows that the increase in the film thickness of the organic layer in the blue light-emitting element 5b hardly affects the light emission characteristics.

Furthermore, the blue light-emitting element 5b is designed to satisfy the first-order interference condition, and thus achieves higher chromaticity compared with the element 5b satisfying the zero-order interference condition. This can offer also an advantageous effect that the chromaticity point of the blue light-emitting element 5b shifts toward a deep blue region. Thus, the color reproduction range necessary for a high-definition display can be ensured.

As described above, according to an embodiment of the present invention, in a full-color display including organic electroluminescent elements of the respective colors, defective spots in the blue light-emitting element 5b can be reduced without failure in the controllability of light emission characteristics.

In the above-described embodiment, the film-thickness adjustment pattern layer 9-3 is formed as a layer having a hole transport function. However, if it is possible to use a material superior in the electron transport property, the film-thickness adjustment pattern layer 9-3 may be provided as a layer having an electron transport function on the cathode-side surface of the blue common light-emitting layer 9b.

Furthermore, in the embodiment, the display 1 is an active-matrix display. However, embodiments of the present invention can be applied also to a simple-matrix display. In the case of a simple-matrix display, the cathodes 13 are formed into a stripe shape intersecting with the anodes 7 formed into a stripe shape, and the red light-emitting elements 5r, the green light-emitting elements 5g, and the blue light-emitting elements 5b are provided at the respective parts at which the cathode 13 and the anode 7 intersect with each other and the organic layer 9 is interposed therebetween.

In the simple-matrix display, a drive circuit for each pixel is not provided over the substrate 3. Therefore, even when the simple-matrix display is formed as a transmissive one that outputs luminescent light through the substrate 3, the aperture ratio of the pixels can be maintained.

In this transmissive display, the anodes 7 disposed over the substrate 3 are used as a half-mirror, while the cathodes 13 are used as a mirror, so that resonated light is extracted from the substrate 3 via the anodes 7. In this case, as the materials of the substrate 3, the anodes 7, and the cathodes 13, materials each having an optical reflective/transmissive characteristic suitable for the corresponding layer are selected and used. In addition, if the simple-matrix display is a transmissive one, the display may have a configuration obtained by reversing the stacking order of the layers from the anode 7 to the cathode 13 in the above-described embodiment.

Furthermore, an embodiment of the present invention may be applied to an active-matrix display that has a configuration obtained by reversing the stacking order of the layers from the anode 7 to the cathode 13 in the above-described embodiment. In the active-matrix display, a drive circuit for each pixel is provided over the substrate 3. Therefore, it is advantageous in terms of ensuring of a high pixel aperture ratio that the display is formed as a top-emission one that outputs luminescent light from the opposite side of the substrate 3. In this case, the materials of the cathode 13 disposed over the substrate 3 and the anodes 7 disposed on the light-output side are adequately so selected that the cathode 13 serves as a mirror and the anodes 7 serve as a half-mirror.

Embodiments of the present invention are effective and can offer the same advantages also in a display that employs organic electroluminescent elements obtained by stacking organic layer units including a light-emitting layer (light-emitting units) as shown in e.g. Japanese Patent Laid-open No. 2003-272860.

### WORKING EXAMPLE

Ten blue light-emitting elements were fabricated of which micro resonator structure was designed to satisfy the first-order interference condition.

The chromaticity and light emission efficiency of the fabricated ten blue light-emitting elements were measured by using a spectral radiance meter with a constant current having a current density of 10 mA/cm2 applied to the blue light-emitting elements. Of the elements, an element from which intended light emission characteristics were obtained was defined as the design center. Furthermore, the sample with the largest film-thickness deviation in the positive direction was defined as Sample 1, while the sample with the largest film-thickness deviation in the negative direction was defined as Sample 2. The evaluation results are shown in Table 1.

TABLE 1

| | | | | Difference in |
|---|---|---|---|---|
| | | | | Light Emission |
| | | | Light Emission | Efficiency from |
| | CIEx | CIEy | Efficiency(cd/A) | Design Center(%) |
| Design | 0.135 | 0.069 | 2.611 | — |
| Center | | | | |
| Sample 1 | 0.133 | 0.074 | 2.844 | 8.9 |
| Sample 2 | 0.137 | 0.064 | 2.322 | −11.1 |

The results of Table 1 show, regarding the light emission characteristics of the blue light-emitting element 5b of which micro resonator structure was designed to satisfy the first-order interference condition, that the difference in the light emission efficiency from the design center falls within a range of ±15%.

Thus, it is confirmed that, even when the structure of the blue light-emitting element 5b is designed to satisfy the first-order interference condition and therefore the film thickness of the organic layer part of the blue light-emitting element 5b is increased compared with the film thickness of a zero-order cavity structure, the difference in the light emission efficiency due to the influence of the thickness increase falls within a range of ±15%, which is allowable for a high-definition display, and the controllability of the light emission characteristics is ensured.

What is claimed is:

1. A display comprising:
a plurality of organic electroluminescent elements having a lower electrode, an organic layer including at least a light-emitting layer, and an upper electrode in this order, the organic layer has a film thickness that allows resonance of luminescent light generated in the light-emitting layer, wherein
the film thickness of the organic layer in a first organic electroluminescent element that generates a first color luminescent light is set larger than the film thickness of the organic layer in a second organic electroluminescent element that generates a second color luminescent light having a wavelength longer than the wavelength of the first color luminescent light.

2. The display according to claim 1, wherein
the film thickness of the organic layer in each of the organic electroluminescent elements is adjusted by the light-emitting layer and a film-thickness adjustment pattern layer that is formed only in the first organic electroluminescent element.

3. The display according to claim 2, wherein
a first light-emitting layer that generates the first color luminescent light is provided as a common layer in the plurality of organic electroluminescent elements, and
a second light-emitting layer that generates the second color luminescent light is provided only in the second organic electroluminescent element.

4. The display according to claim 3, wherein
the film-thickness adjustment pattern layer and the second light-emitting layer are provided by laser transfer method, and
the first light-emitting layer is provided by evaporation.

5. The display according to claim 2, wherein
the film-thickness adjustment pattern layer is provided under the light-emitting layer provided in the first organic electroluminescent element.

6. The display according to claim 2, wherein
the film-thickness adjustment pattern layer has a hole transportability.

7. The display according to claim 1, wherein
the first organic electroluminescent element generates blue luminescent light.

8. A method for manufacturing a display having a plurality of organic electroluminescent elements, each of which having a lower electrode, an organic layer including at least a light-emitting layer, and an upper electrode in this order, the organic layer has a film thickness that allows resonance of a wavelength of luminescent light generated in the light-emitting layer, the method comprising the step of
providing a first organic electroluminescent element that generates a first color luminescent light and a second organic electroluminescent element that generates a second color luminescent light having a wavelength longer than the first color luminescent light, in such a way that the film thickness of the organic layer in the first organic electroluminescent element is set larger than the film thickness of the organic layer in the second organic electroluminescent element.

9. The method for manufacturing a display according to claim 8, wherein
the first light-emitting layer that generates the first color luminescent light is deposited by evaporation;
the second light-emitting layer that generates the second color luminescent light is provided by laser transfer method; and
a film-thickness adjustment pattern layer for adjusting the film thickness of the organic layer in the first organic electroluminescent element is provided by laser transfer method.
